(19) United States
(12) Patent Application Publication
(10) Pub. No.: US 2024/0210521 A1
(43) Pub. Date: Jun. 27, 2024

(54) RADAR DEVICE AND METHOD FOR PRODUCING A RADAR DEVICE

(71) Applicant: Robert Bosch GmbH, Stuttgart (DE)

(72) Inventors: Corinne Grevent, Ostfildern (DE); Philipp Ritter, Saarbruecken (DE); Werner Soergel, Pforzheim (DE); Markus Gonser, Albstadt-Laufen (DE); Andreas Kugler, Alfdorf (DE); Armin Himmelstoss, Weissach Im Tal (DE); Christian Silber, Tuebingen (DE); Klaus Baur, Mietingen (DE); Ralph Nyilas, Korntal-Muenchingen (DE)

(21) Appl. No.: 18/557,257

(22) PCT Filed: Apr. 26, 2022
(86) PCT No.: PCT/EP2022/061028

§ 371 Date: Oct. 25, 2023

(30) Foreign Application Priority Data
Apr. 29, 2021 (DE) 10 2021 204 296.1

(51) Int. Cl. G01S 7/03; G01S 7/02; G01S 13/931; H01P 5/107; H01Q 1/22

(52) U.S. Cl. CPC G01S 7/032; G01S 7/028; H01P 5/107; H01Q 1/2283; G01S 13/931

(57) ABSTRACT

A radar device. The radar device includes a printed circuit board; a signal generation circuit, which is arranged at least indirectly on the printed circuit board, is electrically coupled to the printed circuit board and is designed to generate a radar signal; a waveguide antenna device, which is arranged at least indirectly on the printed circuit board; and a waveguide coupling device, wherein the signal generation circuit is arranged on or in the waveguide coupling device, and wherein the waveguide coupling device is designed to couple the radar signal generated by the signal generation circuit, into the waveguide antenna device.

### FIELD

The present invention relates to a radar device and to a method for producing a radar device. In particular, the present invention relates to a radar device for use in a motor vehicle.

### BACKGROUND INFORMATION

Networked vehicles as well as assisted and autonomous driving will play an increasingly greater role. In this respect, the detection of the vehicle environment is of particular importance. In addition to camera systems, sensors that provide more accurate speed estimates and, even in low light conditions, deliver good measurement results are increasingly used with increasing degree of autonomy. Radar is one such technology that works reliably even in complete darkness or against the sun.

Initially, radar devices were used for comfort functions, such as the adaptive cruise control. Since then, sensor technology has evolved greatly and, today, safety aspects are in the foreground. Most notably, the safety classification of the New Car Assessment Program (NCAP) organizations requires, for a good rating, not only safety in the crash test but also systems that prevent accidents from happening in the first place. For example, assistants for recognizing objects in the blind spot are part of the standard equipment in new vehicles, as are lane-change assistants. Emergency brake assist systems are also required, not only for simple scenarios between vehicles but also for scenarios in which so-called vulnerable road users are involved, e.g., pedestrians or cyclists.

For radar sensor technology, this means constantly increasing requirements with respect to sensitivity and selectivity, which imposes high requirements on the antenna field of the radar sensor. At the same time, costs are to be kept low. In this case, costs can be reduced by integration, e.g., by integrating electrical signal generation, transmission, reception, and processing into a single system on a chip (SoC).

In such single-chip approaches, there are no high-frequency connections between the chips on the circuit board. The conventionally used patch antenna is therefore the only remaining element that the printed circuit board requires for high frequencies. The sensor size is primarily determined by the patch antennas, which occupy a significant portion of the space on the high-frequency printed circuit board.

Besides form factor and size, a further limitation of today's patch antennas is their limited operational frequency bandwidth. Newer automotive radar sensors have increased spatial resolution requirements, which are reflected in operational bandwidths of 4 GHz to 5 GHz. While conventional patch antenna arrays typically have a narrower band, waveguide antennas can cover bandwidths of up to approx. 10 GHz. In addition, waveguide antennas promise better efficiency, lower losses, and a greater field of view in comparison to today's patch antennas. An exemplary waveguide interface is described in U.S. Patent Application Publication No. US 2020/0365971 A1.

Transitioning to such antenna technology could therefore significantly reduce the printed circuit board size and the sensor size and, at the same time, improve the performance of the radar sensor. If the radar chip could additionally be directly coupled into such a waveguide antenna, this would allow the use of cheap printed circuit boards and thus pave the way for more cost-effective and better radar sensors.

A direct coupling between the radar chip and a waveguide antenna is realized by waveguide coupling devices, which are also referred to as waveguide launchers. These waveguide coupling devices must be integrated into the radar chip package so that no millimeter wave signal is transmitted on the printed circuit board.

The waveguide antenna and radar chip may be mounted on opposite sides of the printed circuit board so that a transition via the printed circuit board is required. In this case, the transitions must be precisely, smoothly and evenly metallized in order to achieve good millimeter wave transmission performance. Furthermore, the cooling system is located on the top surface of the housing, which is generally less efficient than a cooling system on the rear side.

Alternatively, the millimeter wave signal may not be transmitted through the printed circuit board but may be directly coupled into the waveguide antenna. The printed circuit board material can therefore be cost-optimized without any millimeter wave requirements or constraints. The heat dissipation can also be optimized by attaching heat sinks to both the top side and the underside of the chip. However, since the millimeter wave is conducted via the mold compound, any change in the electrical properties, e.g., during the production process, due to a changing temperature or due to age, can change or degrade the attenuation in the millimeter wave signal path. In addition, the production of such housings is complex, resulting not only in difficulty in meeting the required tolerances for low high-frequency losses and leakages but also in high producing costs.

### SUMMARY

The present invention provides a radar device and a method for producing a radar device.

Preferred embodiments of the present invention are disclosed herein.

According to a first aspect, the present invention accordingly relates to a radar device. According to an example embodiment of the present invention, the radar device includes a printed circuit board; a signal generation circuit, which is arranged at least indirectly on the printed circuit board, is electrically coupled to the printed circuit board and is designed to generate a radar signal; a waveguide antenna device, which is arranged at least indirectly on the printed circuit board; and a waveguide coupling device, wherein the signal generation circuit is arranged on or in the waveguide coupling device, and wherein the waveguide coupling device is designed to couple the radar signal generated by the signal generation circuit, into the waveguide antenna device.

According to a second aspect, the present invention relates to a method for producing a radar device. According to an example embodiment of the present invention, the method comprises the steps of: providing a printed circuit board; arranging a signal generation circuit at least indirectly on the printed circuit board, wherein the signal generation circuit is electrically coupled to the printed circuit board and is designed to generate a radar signal; forming a waveguide coupling device at least indirectly on the printed circuit board, wherein the signal generation circuit is arranged on or in the waveguide coupling device; and arranging a waveguide antenna device at least indirectly on the printed circuit board, wherein the waveguide coupling device is designed to couple the radar signal generated by the signal generation circuit, into the waveguide antenna device.

The radar device of the present invention can be produced simply and cost-effectively while the millimeter wave losses can be kept low. Furthermore, the radar device can have good properties in terms of bandwidth, system costs, mechanical stability, and reliability.

According to an example embodiment of the present invention, the printed circuit board can be provided for transmitting low-frequency signals only. Furthermore, the printed circuit board provides a common mechanical base for the signal generation circuit (radar chip) and the waveguide antenna device. It is not used for the transmission or conduction of millimeter wave signals and can therefore be implemented in a cost-effective standard process.

According to a preferred embodiment of the radar device of the present invention, the waveguide coupling device comprises a mold compound, which at least partially surrounds the signal generation circuit. The mold compound can be applied by means of transfer molding. The mold compound protects the signal generation circuit from ambient stresses and impacts, such as during assembly of the radar device. However, according to other embodiments, the radar device may also not have any mold compound.

According to a preferred embodiment of the radar device of the present invention, the waveguide coupling device comprises an interposer designed to conduct the radar signal generated by the signal generation circuit, to the waveguide antenna device.

According to a preferred embodiment of the radar device of the present invention, the interposer comprises an integrated waveguide portion in order to conduct the radar signal generated by the signal generation circuit, to the waveguide antenna device.

According to a preferred embodiment of the radar device of the present invention, the interposer comprises an impedance adjustment portion in order to conduct the radar signal generated by the signal generation circuit, to the waveguide antenna device.

According to a preferred embodiment of the radar device of the present invention, an air gap is formed at least in sections between the waveguide coupling device and the waveguide antenna device. Depending on the choice of materials for the different components of the radar device and their mechanical properties (in particular their relative expansion), the air gap enables the compensation of the stresses in the radar device during small movements of the various components relative to one another. The coupling between the printed circuit board and the waveguide antenna device can be designed in such a way that stress compensation and small movements are possible.

According to a preferred embodiment of the radar device of the present invention, the waveguide antenna device is movably or displaceably disposed on the printed circuit board directly or via small pins. As a result, the friction between the waveguide and the printed circuit board can be reduced.

According to a preferred embodiment of the present invention, the radar device comprises a connection layer, which connects the waveguide coupling device at least in sections to the waveguide antenna device. In this embodiment, no air gap or only a partial air gap is thus formed between the waveguide coupling device and the waveguide antenna device. As a result, the mechanical stability can be increased. The materials used can be selected according to their material properties. In particular, the expansion properties of the waveguide coupling device, waveguide antenna device and printed circuit board are coordinated with one another. As a result of the connection of the structures, the radar device has low HF losses that occur at the transition between the interposer of the waveguide coupling device and the transition structure to the waveguide antenna device.

According to a preferred embodiment of the present invention, the connection layer only extends between the waveguide coupling device and the waveguide antenna device. However, there is no fixed connection layer between the waveguide antenna device and the printed circuit board. On the one hand, this enables efficient transmission of the HF signal from the waveguide coupling device to the waveguide antenna device with low losses. On the other hand, small movements of the components relative to one another are still made possible.

According to a preferred embodiment of the radar device of the present invention, the waveguide antenna device comprises a substrate and a cover arranged on the substrate, wherein at least one waveguide is formed at least in sections between the substrate and the cover. As a result, the radar device can be produced cost-effectively.

According to a preferred embodiment of the present invention, the radar device comprises at least one heat sink, which is at least indirectly connected to the signal generation circuit and/or the printed circuit board in order to dissipate heat.

According to a preferred embodiment of the radar device of the present invention, the signal generation circuit is a system-on-a-chip circuit or a monolithic microwave integrated circuit (MMIC).

According to a preferred embodiment of the radar device of the present invention, a heat sink is arranged on the printed circuit board on a side opposite the signal generation circuit. As a result, efficient heat transfer can be enabled.

### BRIEF DESCRIPTION OF THE DRAWINGS

FIG. 1 shows a schematic cross-sectional view of a radar device according to a first embodiment of the present invention.

FIG. 2 shows a schematic cross-sectional view of a radar device according to a second embodiment of the present invention.

FIG. 3 shows a schematic cross-sectional view of a radar device according to a third embodiment of the present invention.

FIG. 4 shows a schematic cross-sectional view of a radar device according to a fourth embodiment of the present invention.

FIG. 5 shows a schematic plan view and cross-sectional view of a radar device according to a fifth embodiment of the present invention.

FIG. 6 shows a schematic cross-sectional view of a radar device according to a sixth embodiment of the present invention.

FIG. 7 shows a schematic cross-sectional view of a radar device according to a seventh embodiment of the present invention.

FIG. 8 shows a schematic cross-sectional view of a radar device according to an eighth embodiment of the present invention.

FIG. 9 shows a schematic plan view of the radar device shown in FIG. 8.

FIG. 10 shows a schematic plan view of a radar device according to a ninth embodiment of the present invention.

FIG. 11 shows a schematic plan view of a radar device according to a tenth embodiment of the present invention.

FIG. 12 shows a schematic cross-sectional view of a radar device according to an eleventh embodiment of the present invention.

FIG. 13 shows a schematic cross-sectional view of a radar device according to a twelfth embodiment of the present invention.

FIG. 14 shows a schematic cross-sectional view of a radar device according to a thirteenth embodiment of the present invention.

FIG. 15 shows a schematic plan view of the radar device shown in FIG. 14.

FIG. 16 shows a schematic cross-sectional view of a radar device according to a fourteenth embodiment of the present invention.

FIG. 17 shows a schematic cross-sectional view of a radar device according to a fifteenth embodiment of the present invention.

FIG. 18 shows a schematic cross-sectional view of a radar device according to a sixteenth embodiment of the present invention.

FIG. 19 shows a schematic cross-sectional view of a radar device according to a seventeenth embodiment of the present invention.

FIG. 20 shows a schematic plan view of the radar device shown in FIG. 19.

FIG. 21 shows a schematic cross-sectional view of a radar device according to an eighteenth embodiment of the present invention.

FIG. 22 shows a schematic cross-sectional view of a radar device according to a nineteenth embodiment of the present invention.

FIG. 23 shows a schematic cross-sectional view of a radar device according to a twentieth embodiment of the present invention.

FIG. 24 shows a schematic cross-sectional view of a radar device according to a twenty-first embodiment of the present invention.

FIG. 25 shows a schematic cross-sectional view of a radar device according to a twenty-second embodiment of the present invention.

FIG. 26 shows a schematic cross-sectional view of a radar device according to a twenty-third embodiment of the present invention.

FIG. 27 shows a flow chart of a method for producing a radar device, according to an example embodiment of the present invention.

In all figures, identical or functionally identical elements and devices are provided with the same reference signs.

### DETAILED DESCRIPTION OF EXAMPLE EMBODIMENTS

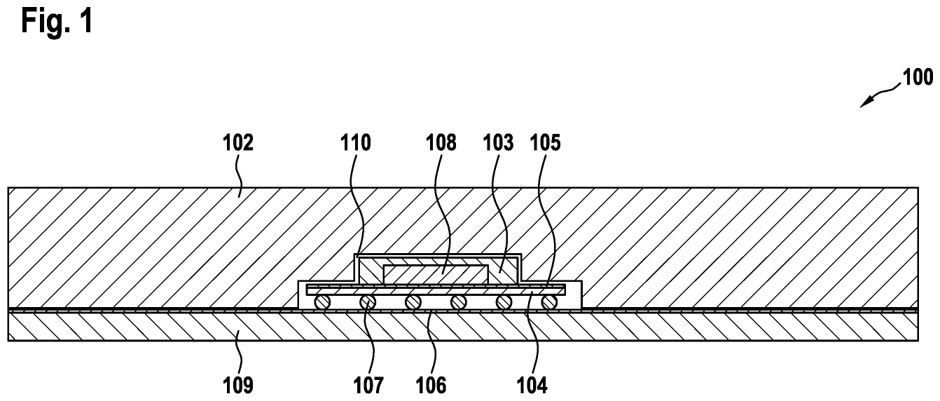

FIG. 1 shows a schematic cross-sectional view of a radar device 100. The radar device 100 comprises a printed circuit board 109 (PCB) with one or more metallization layers 106. The metallization layer 106 is coupled to a signal generation circuit 108, wherein the latter is integrated into a waveguide coupling device.

The waveguide coupling device has a mold compound 103, which surrounds the signal generation circuit 108 on a side facing away from the printed circuit board 109. The waveguide coupling device furthermore comprises an interposer 104 with one or more metallization layers 105. The metallization layers 105, 106 can consist at least partially of copper. In deviation, more or fewer metallization layers may also be provided.

The interposer 104 is not surrounded by the mold compound 103 in the outer regions in order to enable low-loss coupling from the waveguide coupling device into a waveguide antenna device 102. For example, the interposer 104 may have a size of between 11×11 mm² and 20×20 mm².

The signal generation circuit 108 is arranged on the interposer 104 and the interposer 104 is connected to the printed circuit board 109 via solder balls or pads 107 so that a ball-grid-array (BGA)- or land-grid-array (LGA)-like housing is formed. The signal generation circuit 108 is a monolithic microwave integrated circuit (MMIC). According to further embodiments, the signal generation circuit 108 can also be a system-on-a-chip circuit. The signal generation circuit 108 is designed to generate and receive a radar signal (HF signal).

The waveguide antenna device 102 is arranged on the printed circuit board and surrounds the waveguide coupling device and the signal generation circuit 108 integrated therein. An air gap 110 is formed between the waveguide antenna device 102 and the waveguide coupling device. This air gap extends between the waveguide antenna device 102 and the mold compound 103 or the interposer 104 with the metallization layer 105. The air gap 110 can be reduced in size in order to enable physical contact between the waveguide antenna device 102 and the waveguide coupling device. The waveguide antenna device 102 can be or can comprise a metallized injection-molded part.

The waveguide coupling device is designed to couple the radar signal generated by the signal generation circuit 108, into the waveguide antenna device 102. The transition to the waveguide antenna device 102 is advantageously realized on a portion of the interposer 104 that is not surrounded by the mold compound 103, which reduces HF losses and ensures high bandwidth.

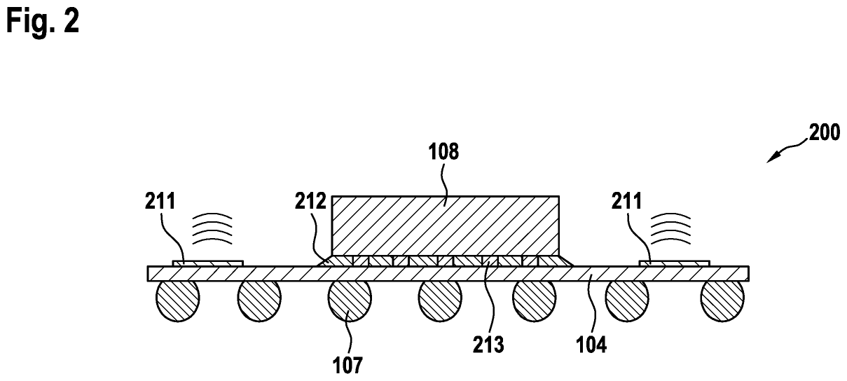

FIG. 2 shows a schematic cross-sectional view of a radar device 200. The signal generation circuit 108 is applied to the interposer 104 by means of flip-chip technology and is connected to the interposer 104 by means of contactings 213. The signal generation circuit 108 is not surrounded by a mold compound. It is thus a bare die structure. In the lateral regions of the printed circuit board, high-frequency (HF) structures 211 are realized in the conductive layers. They are designed to couple the radar signal generated by the signal generation circuit 108, into an adjoining waveguide antenna device (not shown). A capillary underfill (CUF) or mold underfill (MUF) 212 is formed between the signal generation circuit 108 and the interposer 104. In the radar device 200, the waveguide coupling device is formed by the interposer 104 with CUF or MUF 212, contactings 213 and HF structures 211. The printed circuit board 109 is not shown.

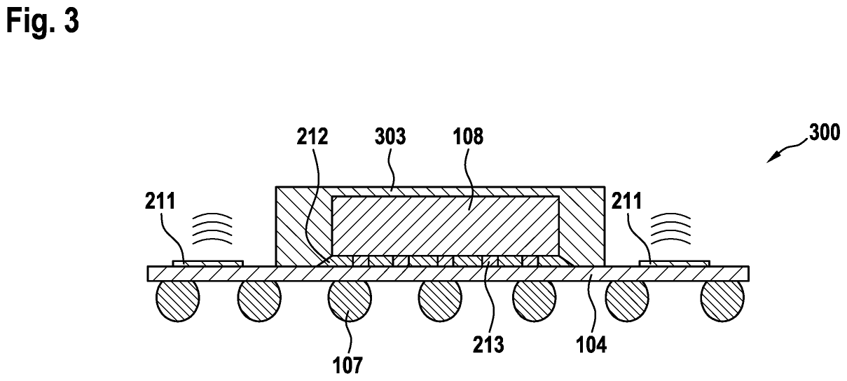

FIG. 3 shows a schematic cross-sectional view of a radar device 300. The structure substantially corresponds to the structure illustrated in FIG. 2. Additionally, the signal generation circuit 108 is partially surrounded by a mold compound 303. However, the lateral regions of the interposer 104 are not surrounded by mold compound 303.

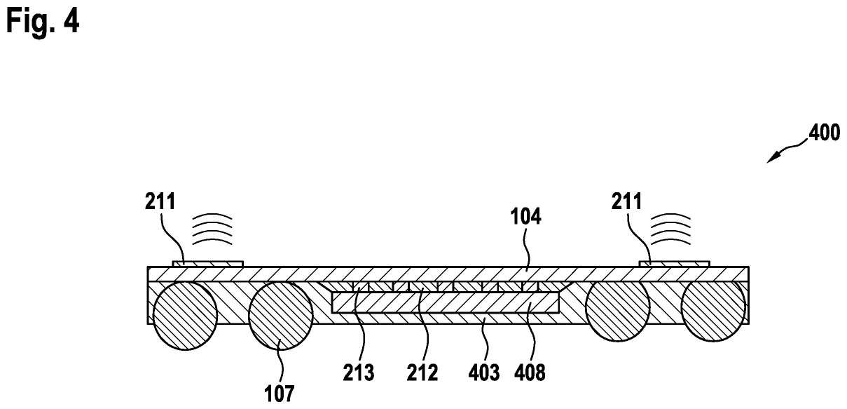

FIG. 4 shows a schematic cross-sectional view of a radar device 400. In this case, the signal generation circuit 408 is arranged on an underside of the interposer 104 and surrounded by mold compound 403. The relevant HF structures 211 are arranged on the top side of the interposer 104, and the HF wave signals are emitted upward and coupled into the waveguide antenna device (not shown).

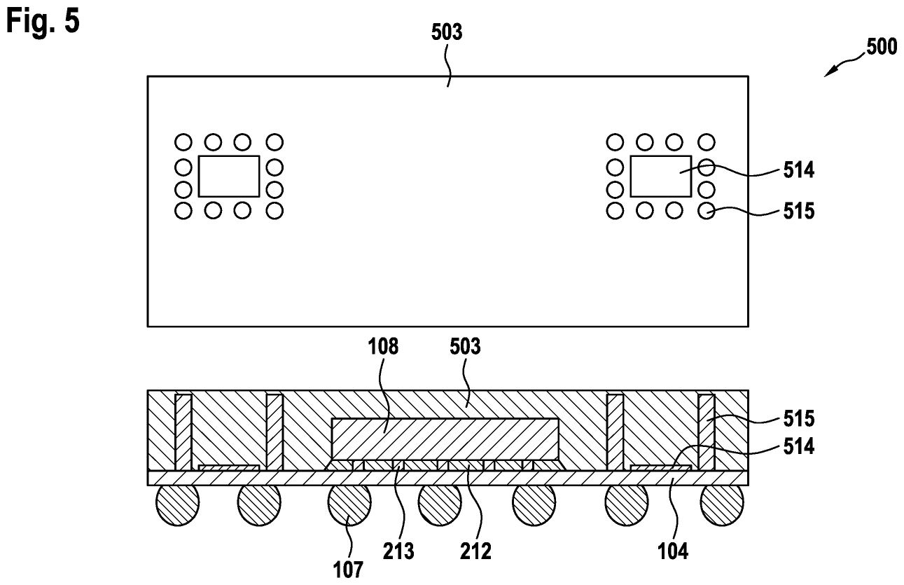

FIG. 5 shows a schematic plan view (top) and cross-sectional view (bottom) of a radar device 500. The mold compound 503 is also formed in the outer regions on the interposer 104, wherein the HF signals are coupled into the waveguide antenna device (not shown) by means of vias 514, 515. The vias 514, 515 extend through the mold compound 503 and are produced by means of through mold via technology.

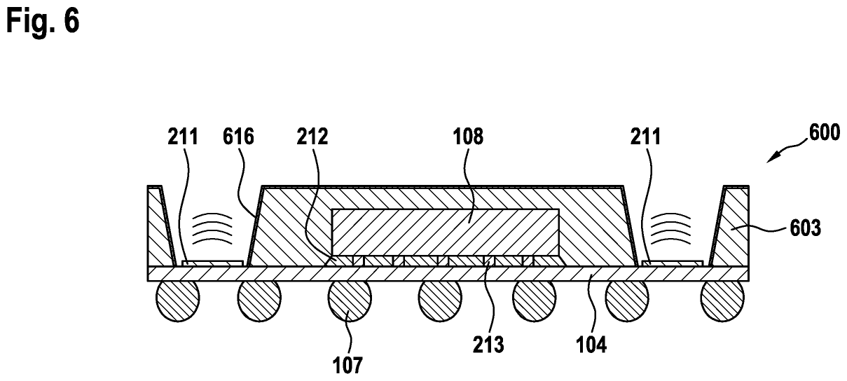

FIG. 6 shows a schematic cross-sectional view of a radar device 600. In this case, a waveguide coupling device surrounded by a mold compound 603 is provided, wherein the HF structures 211 are exposed or at least partially covered by a thin mold compound layer, and the emitted HF signals are guided through a waveguide structure 616 within the mold compound 603, wherein the waveguide structure 616 is preferably metallized toward the outside.

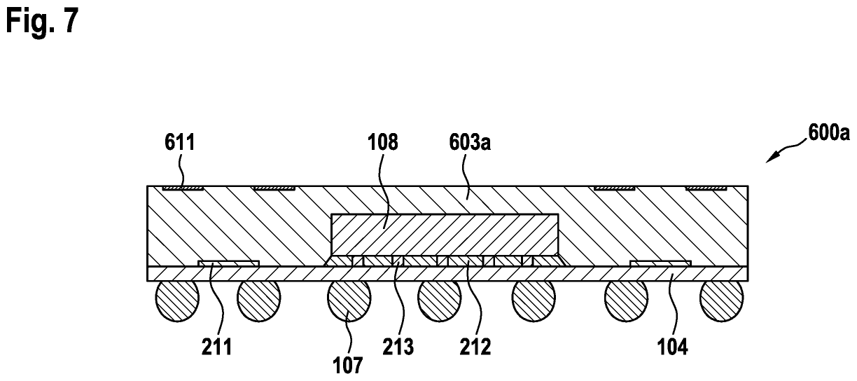

FIG. 7 shows a schematic cross-sectional view of a radar device 600a. The latter differs from the radar device 600 shown in FIG. 6 in that the HF structures 211 are not exposed in the mold compound 603a. Above the HF structures 211, beamforming elements 611 are formed.

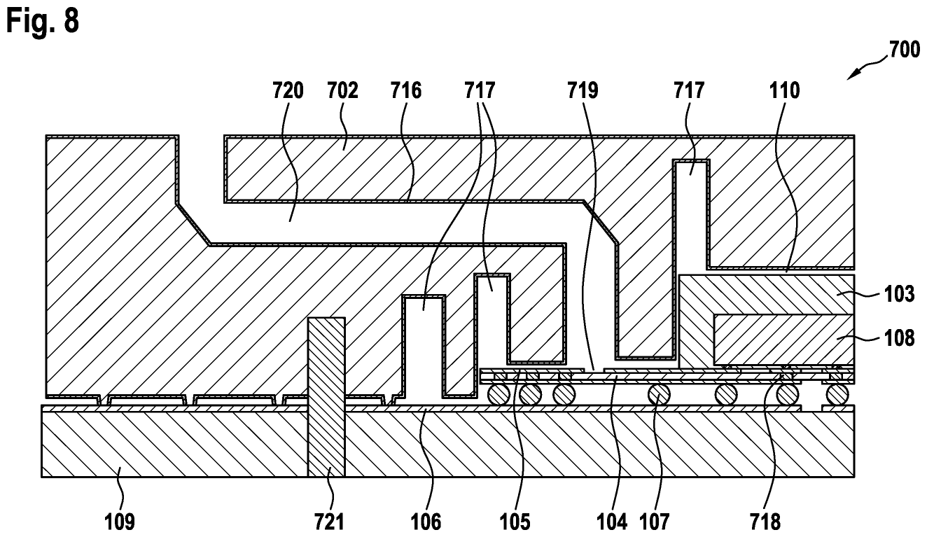

FIG. 8 shows a schematic cross-sectional view of a radar device 700. Only the additions and changes in comparison to the radar device 100 shown in FIG. 1 are explained below. FIG. 8 thus illustrates the contactings 718 (such as copper pillars) extending through the interposer 104, between the signal generation circuit 108 and the solder balls 107. It furthermore illustrates that a region 719 of the metallization layer 105 formed on the interposer 104 is exposed in order to couple the HF signals, which are transmitted via the interposer 104 and have been generated by the signal generation circuit 108, into waveguide channels 720 of the waveguide antenna device 702. The waveguide antenna device 702 comprises a metallization layer 716.

Furthermore, air-filled cavities 717 are formed in the lateral regions next to the waveguide channels 720. For HF signals transmitted through the air gap 110, the cavities serve as λ/4 trap so that there is a reduction in HF leakages and cross-couplings. Three air-filled cavities 717 are illustrated, one near the signal generation circuit 108 at the edge of the interposer 104, one on the side of the interposer 104, and one on the side of the printed circuit board 109. However, according to further embodiments, there can also be more or fewer cavities 717.

According to further embodiments, the cavities 717 can surround the region 719 in whole or in part.

According to further embodiments, the cavities 717 can be replaced by compensation structures in the interposer 104 up to or into the printed circuit board 109.

The correct positioning of the waveguide antenna device 702 relative to the printed circuit board 109 and to the waveguide coupling device is improved with the aid of a centering 721 by pins. In further embodiments, self-centering structures can be provided. For this purpose, the underside of the waveguide antenna device 702 can be structured with a solder island, the total base area of which is adjusted to the printed circuit board top side, wherein a reflow soldering process serves to center the waveguide antenna device 702. In order to reduce stress, the centering components, such as pins or the like, can be arranged near the waveguide coupling device.

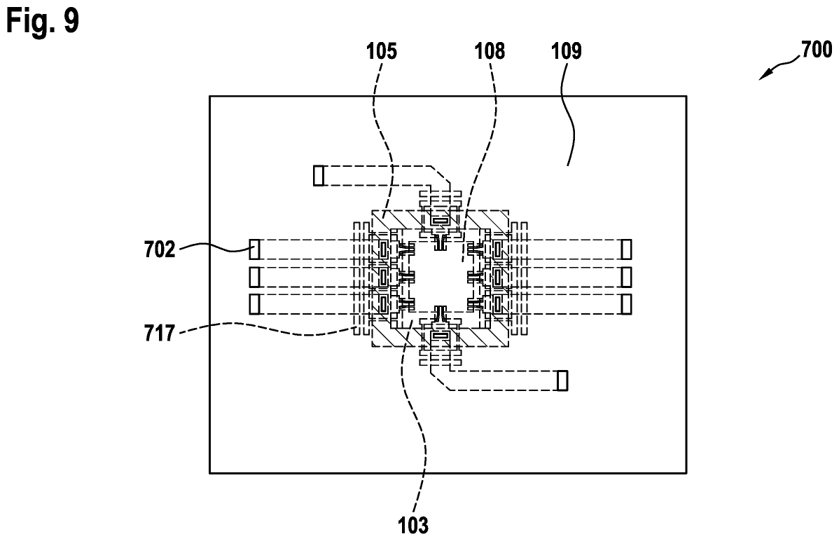

FIG. 9 shows a schematic plan view of the radar device 700 shown in FIG. 8.

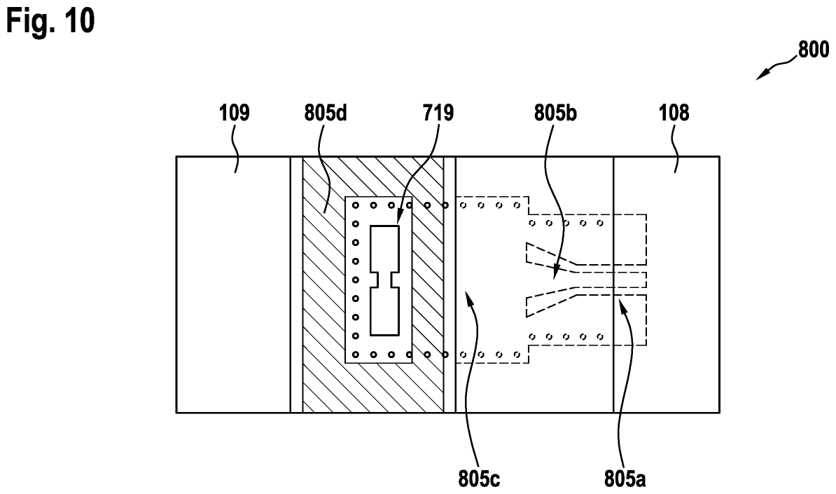

FIG. 10 shows a schematic plan view of a radar device 800, wherein only the coupling of the radar signals by means of the waveguide coupling device are illustrated in more detail. The remaining components of the radar device 800 can correspond to one of the embodiments described above. The interposer here comprises a grounded coplanar portion 805a coupled to the signal generation circuit 108, an adjoining transition region 805b, an integrated waveguide portion 805c, and a portion 805d not surrounded by mold compound, in order to conduct the radar signal generated by the signal generation circuit 108, to the waveguide antenna device (not shown).

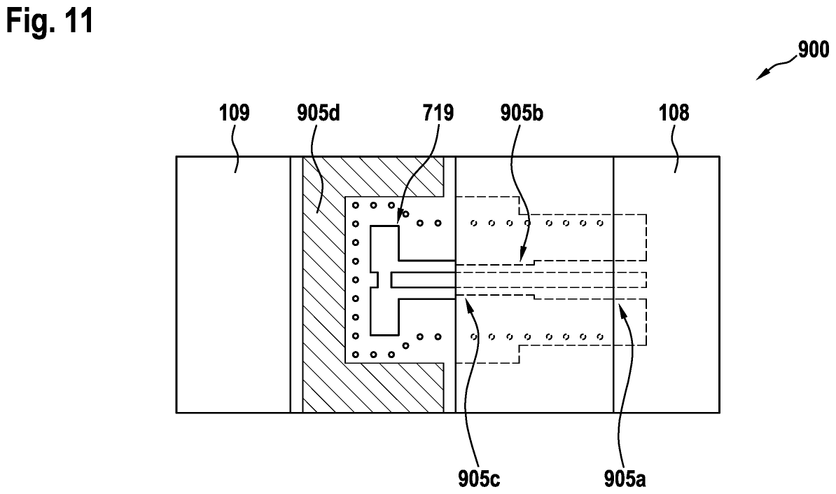

FIG. 11 shows a schematic plan view of a radar device 900. The structure is similar to the structure of the radar device 800 illustrated in FIG. 10. The interposer here comprises a grounded coplanar portion 905a coupled to the signal generation circuit 108, an adjoining impedance adjustment portion 905b, a transition region 905c, and a portion 905d not surrounded by mold compound, in order to conduct the radar signal generated by the signal generation circuit 108, to the waveguide antenna device (not shown).

The coupling mechanisms illustrated in FIGS. 10 and 11 can also be used in the other radar devices illustrated in the figures.

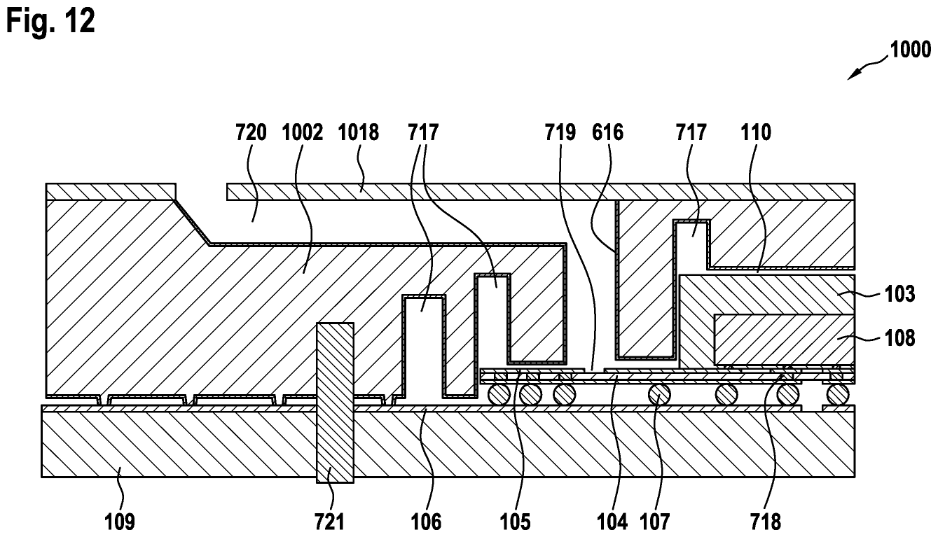

FIG. 12 shows a schematic cross-sectional view of a radar device 1000. The structure substantially corresponds to the structure of the radar device 700 shown in FIG. 8. The waveguide antenna device 1002 is manufactured from blocks, which, in the assembled state, form a three-dimensional structure. The waveguide antenna device 1002 is realized with only one block and a planar cover 1018. The blocks can be produced from forged metal, metal sheets or molded composites, e.g., conductive plastics or composites, or plastics that are metallized in a post-molding process.

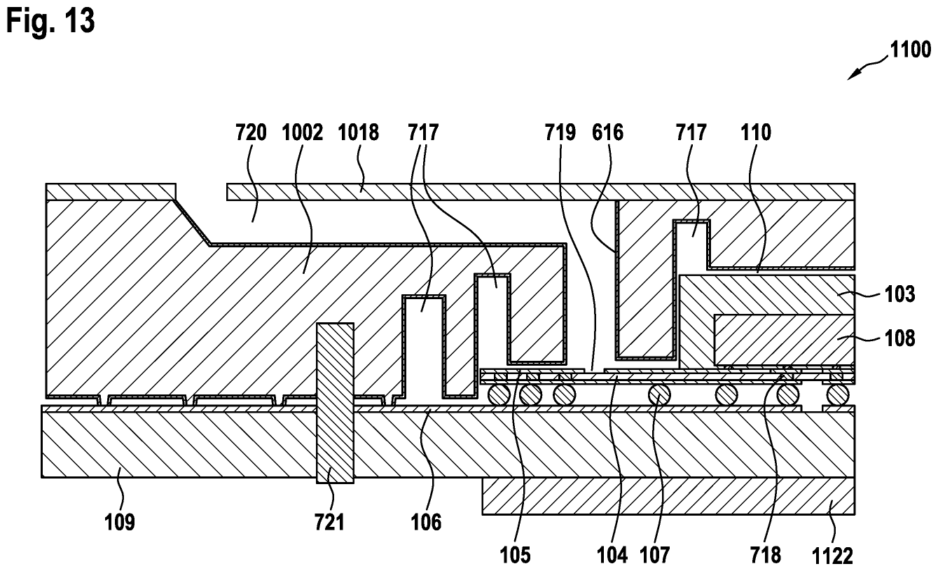

FIG. 13 shows a schematic cross-sectional view of a radar device 1100. The structure of the radar device 1100 substantially corresponds to the structure of the radar device 1000 shown in FIG. 12. Additionally, a thermal heat sink 1122 is arranged on the rear side of the printed circuit board 109.

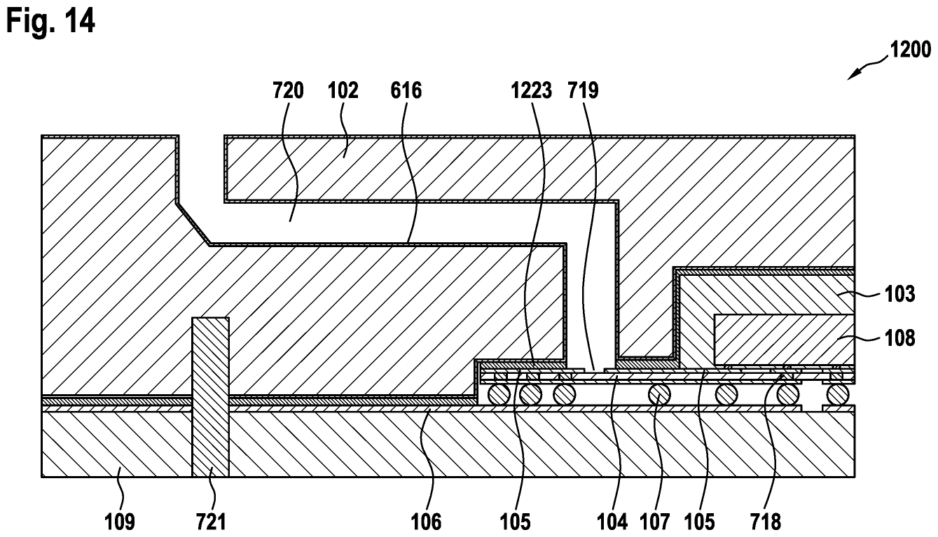

FIG. 14 shows a schematic cross-sectional view of a radar device 1200 that substantially corresponds to the radar device 700 shown in FIG. 8. In contrast to the radar device 700 shown in FIG. 8, the connection between waveguide coupling device, waveguide antenna device 102 and printed circuit board 109 is realized such that the waveguide antenna device 102 is fixedly attached to both the waveguide coupling device and the printed circuit board 109. The fixed connection 1223 between the waveguide antenna device 102 and the waveguide coupling device is realized with a conductive and/or non-conductive adhesive or tape or a solder. Due to the continuous connection, the cavities 717 can be dispensed with.

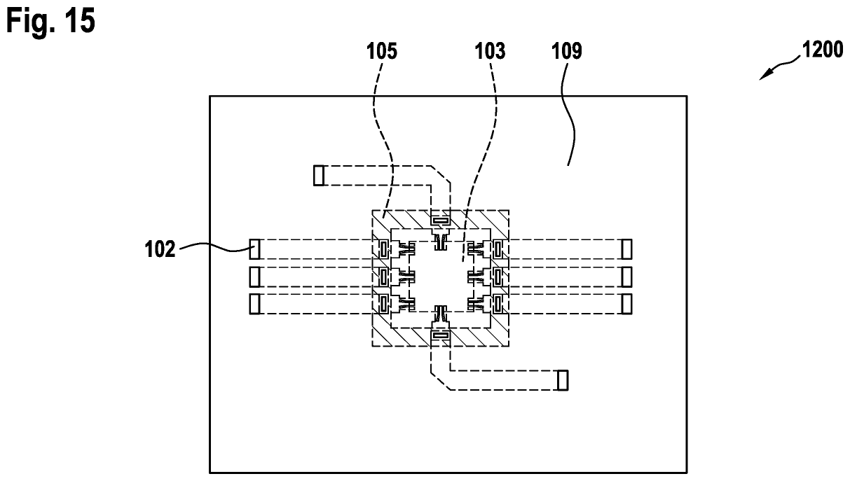

FIG. 15 shows a schematic plan view of the radar device 1200 shown in FIG. 14.

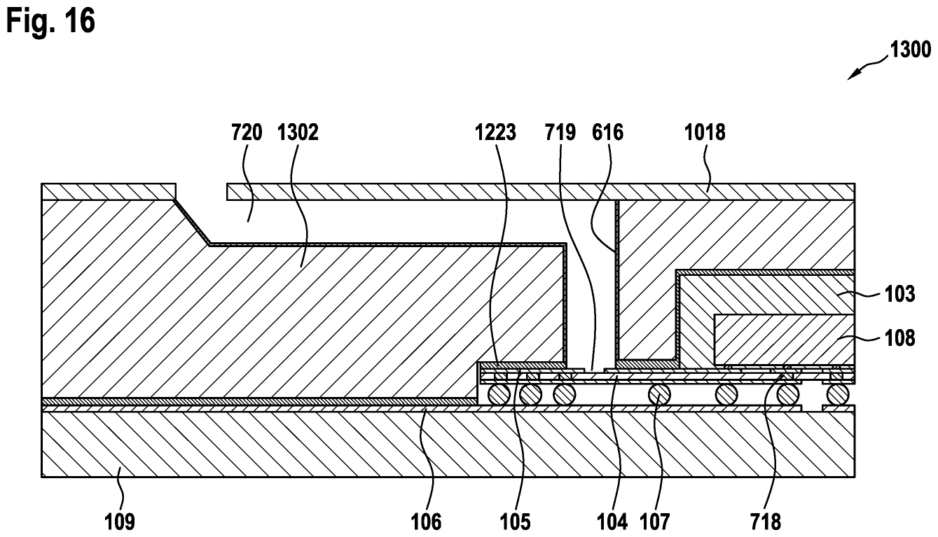

FIG. 16 shows a schematic cross-sectional view of a radar device 1300 that substantially corresponds to the radar device 1000 shown in FIG. 12. In contrast to the radar device 1000 shown in FIG. 12, the connection between waveguide coupling device, waveguide antenna device 1302 and printed circuit board 109 is realized such that the waveguide antenna device 1302 is fixedly attached to both the waveguide coupling device and the printed circuit board 109.

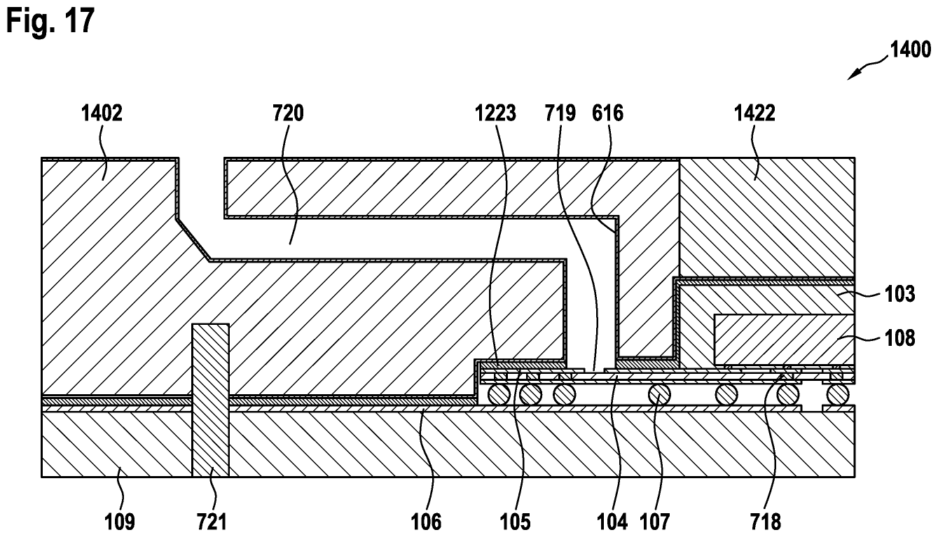

FIG. 17 shows a schematic cross-sectional view of a radar device 1400 that substantially corresponds to the radar device 1100 shown in FIG. 8. In contrast to the radar device 1100 shown in FIG. 8, the connection between waveguide coupling device, waveguide antenna device 1402 and printed circuit board 109 is realized such that the waveguide antenna device 1402 is fixedly attached to both the waveguide coupling device and the printed circuit board 109. A further difference is the additional heat sink 1422 formed on a top side of the waveguide coupling device. Additionally, or alternatively, a heat sink can be formed on the underside of the printed circuit board 109.

Thermal cooling of the radar device 1400 can be further improved through the use of a heat-conducting adhesive or solder in that an efficient cooling path from the signal generation circuit 108 to the printed circuit board 109 along the mold compound 103, the interposer 104, and the metallization layer 106 is created. At the same time, the waveguide antenna device 1402 itself acts as a cooling element.

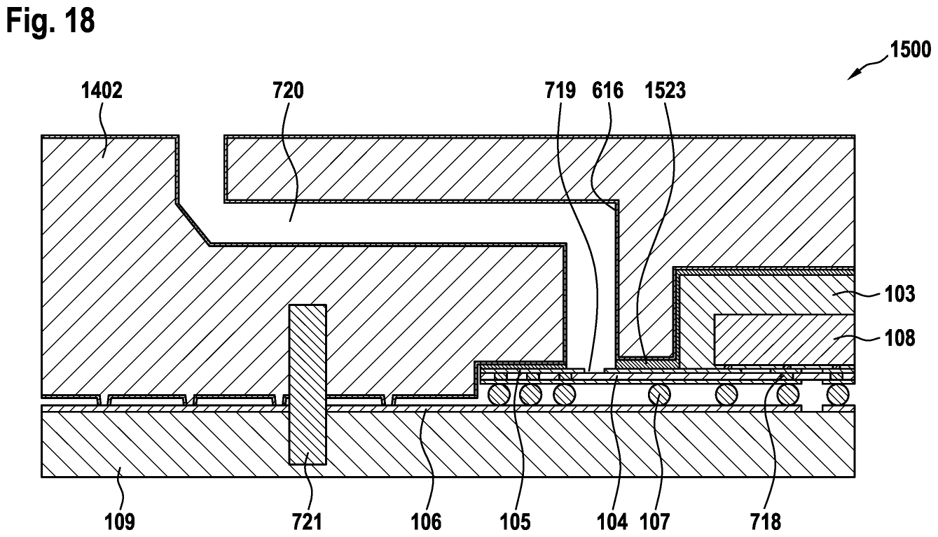

FIG. 18 shows a schematic cross-sectional view of a radar device 1500 that substantially corresponds to the radar device 1200 shown in FIG. 14. In contrast to the radar device 1200 shown in FIG. 14, the connection 1523 extends only between the waveguide coupling device and the waveguide antenna device 1402. This enables efficient transmission of the HF signal from the waveguide coupling device to the waveguide antenna device 102 with low losses. However, there is no fixed connection layer between the waveguide antenna device 1402 and the printed circuit board 109. The waveguide antenna device 102 can be arranged on the printed circuit board with or without pins so that small movements are possible. This is an advantage for the mechanical stability of the assembly over time and under stress, even if the mechanical properties of the different parts are not perfectly coordinated with one another. The fastening of the printed circuit board to the waveguide is designed such that small movements and corresponding stress compensation are possible.

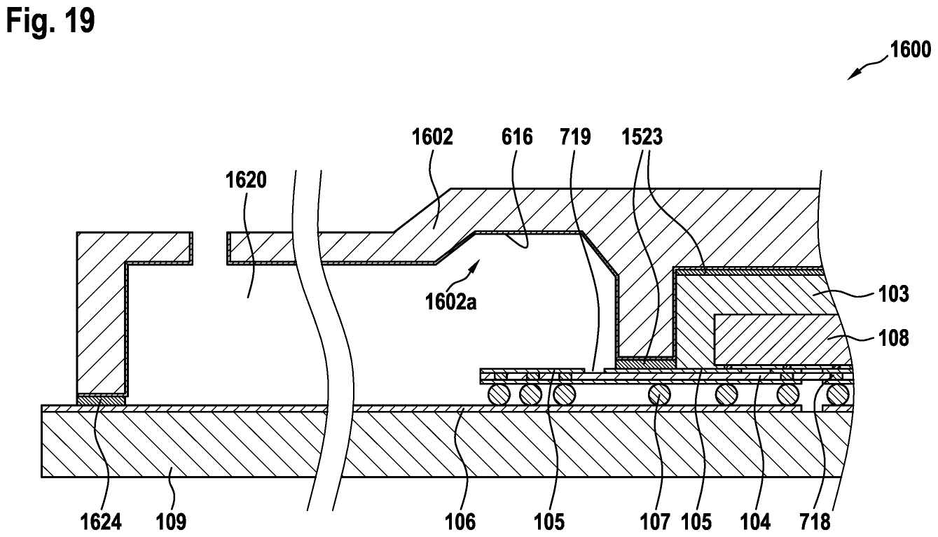

FIG. 19 shows a schematic cross-sectional view of a radar device 1600. The coupling portion of the waveguide antenna device 1602 is integrally formed from a monolithic block, which represents a cost advantage. As a result, a waveguide channel 1620 is formed with an impedance adjustment portion 1602a. The monolithic waveguide antenna block forms the three of four sides of the embedded waveguide channel 1620. The metallization layer 106 of the printed circuit board 109 serves as the fourth wall of the wave guide channel 1620. The printed circuit board 109 and the waveguide antenna device 1602 are connected by a conductive adhesive or solder 1624, which is formed over the entire or part of the surface area.

As a result of the shown structure of the radar device 1600, the radar device 1600 can be produced cost-effectively since the waveguide antenna device 1602 is realized with only one external block. In order to achieve a low-loss transition between the waveguide coupling device and the waveguide antenna device 1602, the waveguide antenna device 1602 and the transition region of the waveguide coupling device are joined by means of a highly conductivity adhesive or solder 1523 and by means of an impedance adjustment portion 1602a in the launcher region.

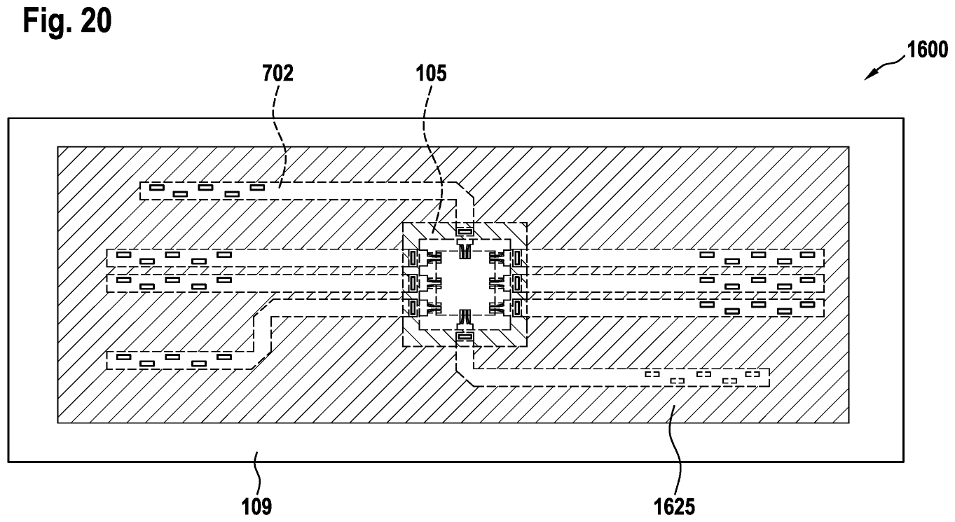

FIG. 20 shows a schematic plan view of the radar device 1600 shown in FIG. 19. In the region 1625, the waveguide antenna device 102 is connected to the metallization layer 106 of the printed circuit board 109.

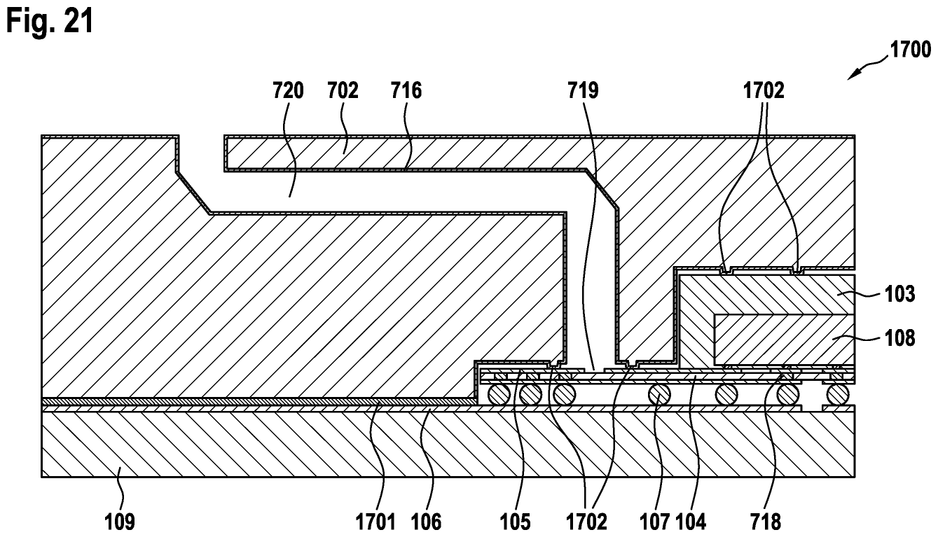

FIG. 21 shows a schematic cross-sectional view of a radar device 1700. The waveguide antenna device 702 is glued or soldered to the printed circuit board 109 via a connection layer 1701. However, there is no fixed or full connection layer between the waveguide antenna device 702 and the waveguide coupling device. Pins, conductive pastes, adhesives, or webs 1702, which can be metallized or can be made of metal and are directly in contact with the waveguide coupling device, are formed or attached in the waveguide antenna device 702. The pins, pastes, adhesives or webs 1702 can be applied onto the waveguide coupling device and are directly in contact with the waveguide antenna device 702. In the region 719 from the signal transition between the interposer 104 and the waveguide antenna device 702, the pins or bars are placed and shaped such that they form a channel for the HF signal and thus enable a good transition of the signal from the interposer 104 into the waveguide antenna device 702. The radar device 1700 also allows for small movements of the waveguide antenna device 702 relative to the waveguide coupling device, which is a mechanical advantage.

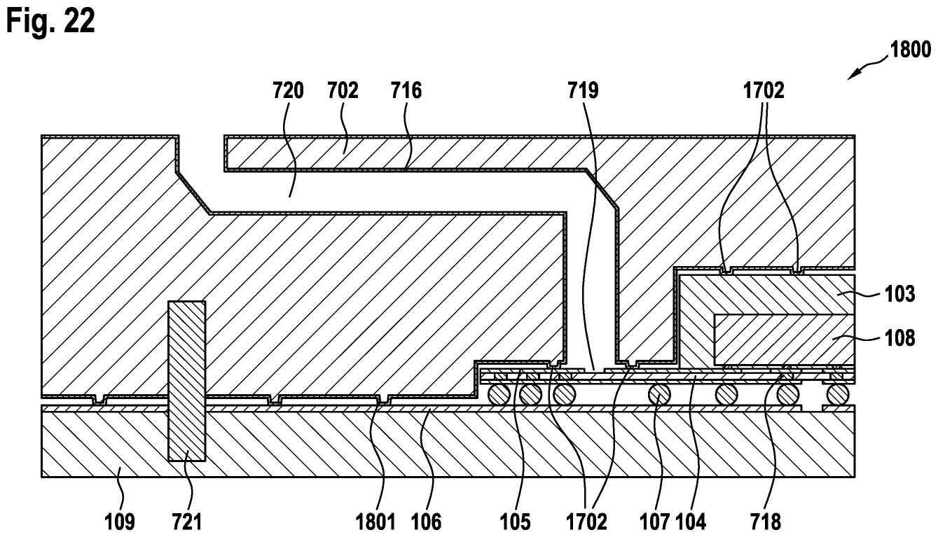

FIG. 22 shows a schematic cross-sectional view of a radar device 1800. The latter differs from the radar device 1700 shown in FIG. 21 in that no connection layer is formed between the waveguide antenna device 702 and the printed circuit board 109.

Rather, pins or webs 1801 are also formed in this region. Furthermore, a centering 721 is provided.

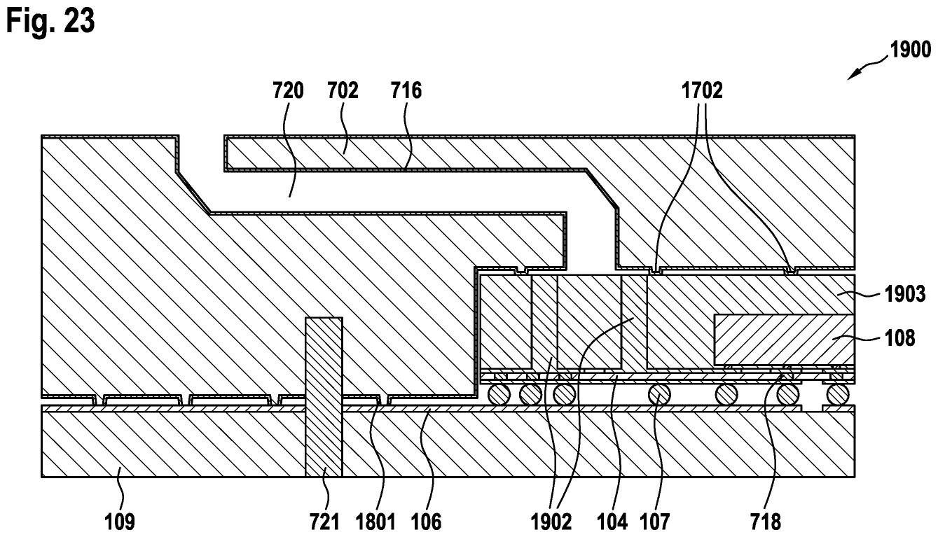

FIG. 23 shows a schematic cross-sectional view of a radar device 1900, which differs from the radar device 1800 shown in FIG. 22 in that the coupling of the HF signal into the waveguide channels 720 takes place by means of vias 1902 through the mold compound 1903.

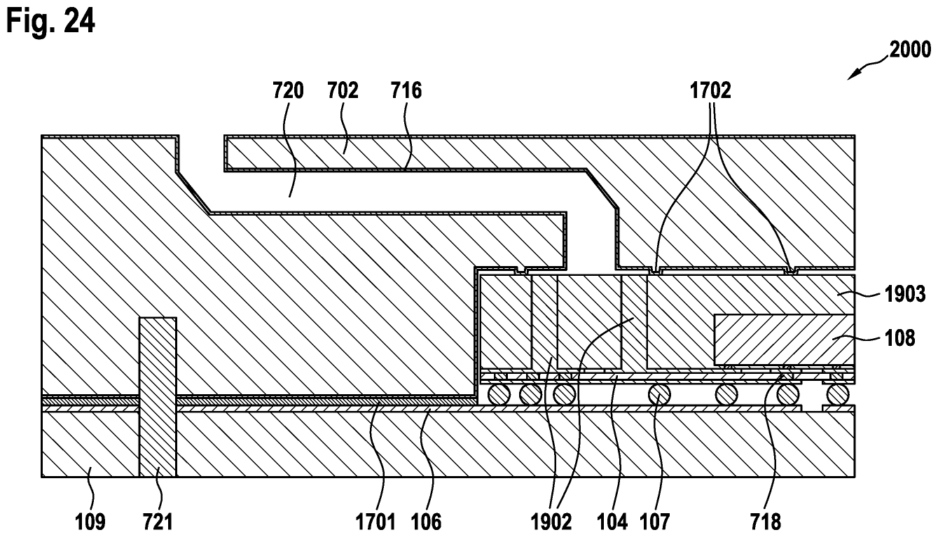

FIG. 24 shows a schematic cross-sectional view of a radar device 2000, which differs from the radar device 1900 shown in FIG. 23 in that a connection layer 1701 as in FIG. 21 is provided.

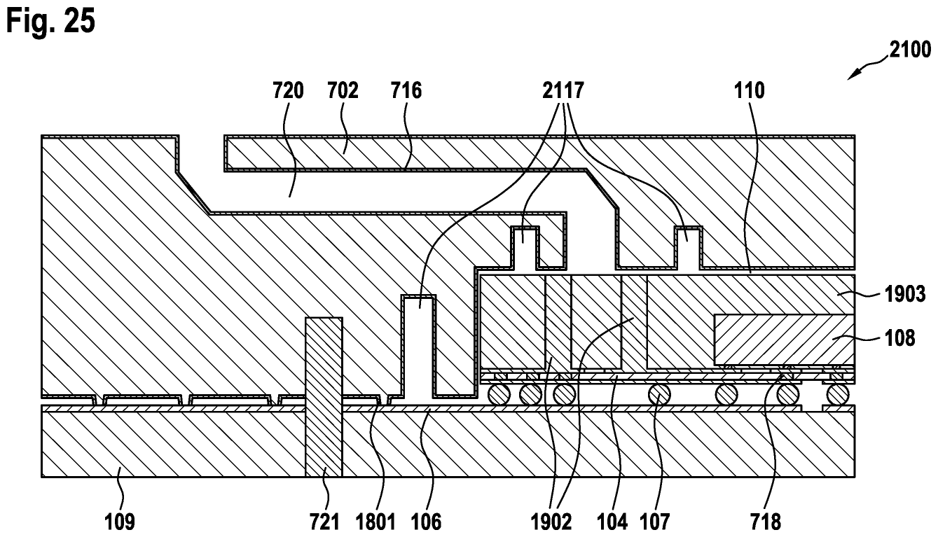

FIG. 25 shows a schematic cross-sectional view of a radar device 2100, which differs from the radar device 1900 shown in FIG. 23 in that air-filled cavities 2117 are provided.

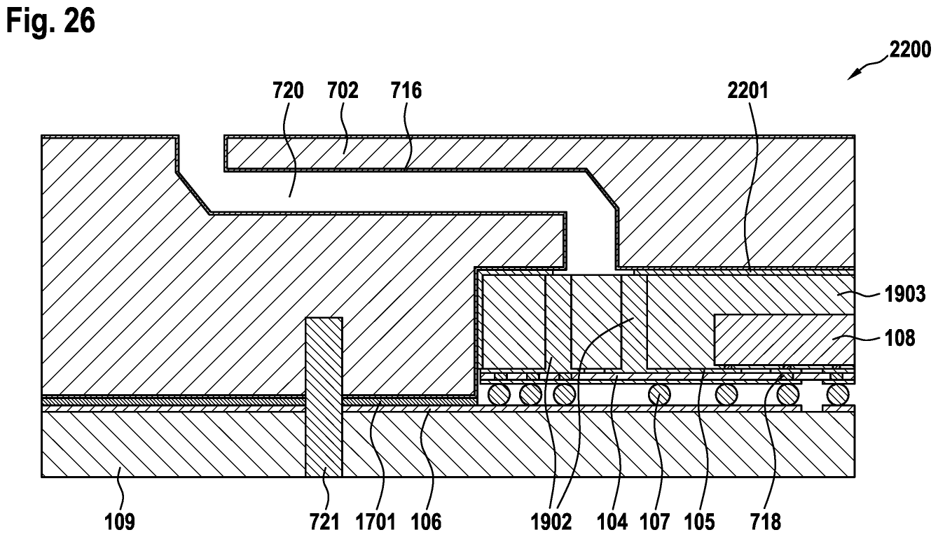

FIG. 26 shows a schematic cross-sectional view of a radar device 2200, which differs from the radar device 2000 shown in FIG. 24 in that a further connection layer 2201 is formed between the mold compound 1903 and the waveguide antenna device 702.

In further embodiments, all radar devices shown above can have a planar cover (as in FIG. 12) and/or at least one heat sink (as in FIG. 17).

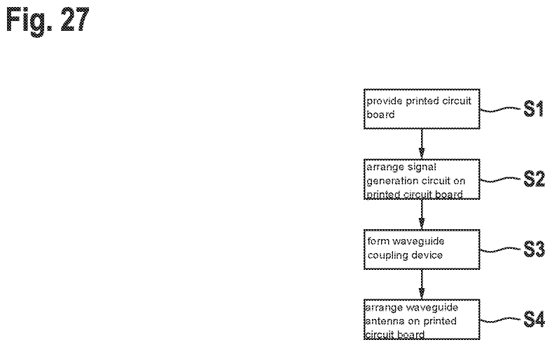

FIG. 27 shows a flow chart of a method for producing a radar device, in particular one of the radar devices described above.

In a first step S1, a printed circuit board is provided.

In a second step S2, a signal generation circuit is arranged at least indirectly on the printed circuit board, wherein the signal generation circuit is electrically coupled to the printed circuit board and is designed to generate a radar signal.

In a third step S3, a waveguide coupling device is formed, wherein the signal generation circuit is arranged on or in the waveguide coupling device.

In a fourth step S4, a waveguide antenna device is arranged at least indirectly on the printed circuit board.

The waveguide coupling device is designed to couple the radar signal generated by the signal generation circuit, into the waveguide antenna device.

1-10. (canceled)

11. A radar device, comprising:
a printed circuit board;
a signal generation circuit, which is arranged at least indirectly on the printed circuit board, is electrically coupled to the printed circuit board, and is configured to generate a radar signal;
a waveguide antenna device, which is arranged at least indirectly on the printed circuit board; and
a waveguide coupling device, wherein the signal generation circuit is arranged on or in the waveguide coupling device, and wherein the waveguide coupling device is configured to couple the radar signal generated by the signal generation circuit, into the waveguide antenna device.

12. The radar device according to claim 11, wherein the waveguide coupling device includes a mold compound which at least partially surrounds the signal generation circuit.

13. The radar device according to claim 11, wherein the waveguide coupling device includes an interposer which is configured to conduct the radar signal generated by the signal generation circuit, to the waveguide antenna device.

14. The radar device according to claim 13, wherein the interposer includes an integrated waveguide portion or an impedance adjustment portion, to conduct the radar signal generated by the signal generation circuit to the waveguide antenna device.

15. The radar device according to claim 11, wherein an air gap is formed at least in sections between the waveguide coupling device and the waveguide antenna device.

16. The radar device according to claim 11, further comprising:
a connection layer, which connects the waveguide coupling device at least in sections to the waveguide antenna device.

17. The radar device according to claim 11, wherein the waveguide antenna device includes a substrate, and a cover arranged on the substrate, wherein at least one waveguide is formed at least in sections between the substrate and the cover.

18. The radar device according to claim 11, further comprising:
at least one heat sink, which is at least indirectly connected to the signal generation circuit and/or the printed circuit board to dissipate heat.

19. The radar device according to claim 11, wherein the signal generation circuit is a system-on-a-chip circuit or a monolithic microwave integrated circuit.

20. A method for producing a radar device, comprising the following steps:
providing a printed circuit board;
arranging a signal generation circuit at least indirectly on the printed circuit board, wherein the signal generation circuit is electrically coupled to the printed circuit board and is configured to generate a radar signal;
forming a waveguide coupling device at least indirectly on the printed circuit board, wherein the signal generation circuit is arranged on or in the waveguide coupling device; and
arranging a waveguide antenna device at least indirectly on the printed circuit board;
wherein the waveguide coupling device is configured to couple the radar signal generated by the signal generation circuit, into the waveguide antenna device.
